(19) United States
(12) Patent Application Publication
(10) Pub. No.: US 2026/0328898 A1
(43) Pub. Date: Oct. 22, 2026

(54) Melting Chamber and Device to Perform Distance Measurements in the Interior Space of a Melting Chamber

(71) Applicant: OndoSense GmbH, Freiburg (DE)

(72) Inventors: Axel Hülsmann, Freiburg (DE); Matthias Meisenheimer, Freiburg (DE); Alexandre Massagli, Sorocaba (BR)

(21) Appl. No.: 19/648,019

(22) Filed: Apr. 15, 2026

(30) Foreign Application Priority Data
Apr. 16, 2025 (DE) 102025115039.7

(51) Int. Cl. G01S 7/282; G01B 7/14; G01B 15/00; G01S 13/10; H05K 7/20

(52) U.S. Cl. CPC G01S 7/282; G01B 7/14; G01B 15/00; G01S 13/10; H05K 7/20145

(57) ABSTRACT

A device to perform distance measurements on a melted mass located in the interior space of a melting chamber and/or a bulk material to be melted, located in the interior space, has a radar system, which has at least one radar antenna to emit and receive radar beams, and an interacting radar electronics unit, which is designed for distance measurement according to the time-of-flight principle. The device has a beam control tube with an inner wall delineating a tube inner cavity that is reflecting for the radar beams. The beam control tube is open for the radar beams at both its axial ends, and the radar antenna faces one of the axial ends of the beam control tube. The radar system is designed and oriented so that the radar beams it emits go through the tube inner cavity of the beam control tube to the opposing other axial end of the beam control tube, and exit the beam control tube there.

### CROSS-REFERENCE TO RELATED APPLICATION

This application claims priority to German Patent Application No. 102025115039.7 filed Apr. 16, 2025, the disclosure of which is hereby incorporated by reference in its entirety.

### BACKGROUND OF THE INVENTION

### Field of the Invention

The invention relates to a device to perform distance measurements on a melted mass located in the interior of a melting chamber and/or a bulk material to be melted, located in the interior space, equipped with a radar system, which has at least one radar antenna to emit and receive radar beams, and an interacting radar electronics unit, for distance measurement according to the time-of-flight principle. In addition, the invention relates to a melting furnace, with such a device, whereby the melting furnace has a melting chamber delineated by exterior walls, which delineates an interior space with a receiving area for a molten mass, and whereby at least one exterior wall has a wall opening arranged higher than the receiving area for the molten mass.

### Description of Related Art

A device of this type and a melting furnace of this type are known from EP 0 633 441 A1. The melting furnace has a melting chamber delineated by a floor, side walls, and a ceiling, which chamber defines an inner space with a receiving area for the molten mass in a section close to the floor that extends up to a level at which the melting chamber has an overflow. For heating, the melting chamber has several heating elements, which are arranged on the ceiling of the melting chamber, above the receiving area for the molten mass. A radar system to measure the level of the molten mass is arranged on the ceiling of the melting chamber. To emit and receive radar beams, the radar system has a radar antenna designed as a horn antenna, and a radar electronics unit that interacts with it. At the position where the radar system is located, the ceiling of the melting chamber has a ceiling opening in which the radar antenna is arranged. Under the radar antenna, which is oriented on the receiving area for the molten mass, a radar-transparent window is arranged in the ceiling opening, which window is tightly connected, at its outer edge, to the ceiling of the chamber. This is intended to prevent hot gases from the melting chamber from reaching the radar system through the ceiling opening.

Above the radar antenna, the radar system has an electronics housing in which the radar electronics unit is arranged. A lower section of the electronics housing extends into the ceiling opening and the rest of the electronics housing projects out of the ceiling opening up to beyond the ceiling surface facing the inner cavity of the melting chamber.

To protect the radar electronics unit from excessively high temperatures and the most adverse ambient influences, the electronics housing is arranged in a radar housing, which has a tube section as a housing wall, which section is oriented with its longitudinal axis orthogonal to the plane that stretches from the ceiling of the melting chamber, and has a lower section that extends into the ceiling opening. The tube section is closed by a cover at its upper end, and, on its inner wall, at a distance from the cover, has an inner flange on which the floor of the electronics housing is positioned. Between the electronics housing and the tube section as well as between the electronics housing and the cover there is an intermediate space in which an inlet opening to feed cooling gas and an outlet for the cooling gas are arranged. At its lower end, facing the radar-transparent window, the tube section has an opening through which the radar beams penetrate.

The cross-section dimensions of the ceiling opening are larger than the corresponding cross-section dimensions of the radar housing and larger than the corresponding cross-section dimensions of the electronics housing. This leads to large openings in the thermal insulation of the melting chamber.

### SUMMARY OF THE INVENTION

The task of the invention is to create a device of the type mentioned above which, when it is mounted on a wall opening of a melting chamber of the type mentioned above, enables low thermal losses at the wall opening while operating the melting chamber. In addition, the task is to specify a melting chamber with such a device.

With regard to the device of the type mentioned above, this task is accomplished in that the device has a beam control tube with an inner wall that reflects the radar beams and surrounds a tube inner cavity, in that the beam control tube is open at both axial ends for the radar beams and the radar antenna faces away from one of the axial ends of the beam control tube, and the radar system is designed and oriented so that the radar beams it emits go through the tube inner cavity of the beam control tube to the opposing other axial end of the beam control tube, and exit the beam control tube there.

Because the radar beams emitted from the radar antenna can be reflected on the inner wall of the beam control tube while passing through the beam control tube, a relatively small tube cross-section is already sufficient to guide the radar beams with low loss from the end of the beam control tube that faces the radar antenna to the opposing other end of the beam control tube. The device according to the invention can, in this manner, be arranged on a melting furnace having an outer wall with a wall opening, such that the radar system is located outside the melting chamber of the melting furnace and that the beam control tube passes through at least one section of the wall opening adjacent to the melting chamber, in order to guide the radar beams emitted from the radar antenna through the beam control tube and into the melting chamber. Radar beams reflected by the molten melt in the melting chamber and/or material to be melted in it are guided through the beam control tube and on to the radar antenna.

In an advantageous manner, the device according to the invention enables the radar beams to be guided at low loss through a wall opening with a small cross-section, without the radar beams being absorbed at the edge of the wall surrounding the wall opening. If the wall has thermal insulation, as is usually the case for an outer wall of a melting furnace, absorption of the radar beams by the thermal insulation, which can contain mineral wool, for example, is avoided. Because of the low cross-section of the wall opening, there is little thermal loss at the wall opening during operation of the melting furnace. This also reduces the thermal load on the radar electronics unit.

It is true that the reflection of the radar beams on the inner wall can lead to radar beams that are emitted from the radar antenna at different angles and coupled into the beam control tube, reach the axial end of the beam control tube, which is at a distance from the radar system, on travel paths of different lengths. As a result, measurement inaccuracies can occur during the distance measurement according to the time-of-flight principle. For specific applications, e.g., measuring the level of a molten mass in a melting furnace, this can be tolerated, however.

The beam control tube preferably consists of metal. However, it can also consist of another material, which is suitable for the thermal load arising from a melting furnace and reflects the radar beams, especially when they impact at a flat angle on the inner wall of the beam control tube. Such a material is ceramic, for example. The beam control tube can have a polygonal or round cross-section.

The radar preferably works according to the known FMCW principle which, after mixing the transmission signal with the receive signal, creates a low-frequency spectrum whose maxima can be assigned to the reflection distances. The frequencies of the maxima are proportional to the distances of the reflections. Interfering reflections are mostly eliminated, because for the distance measurement to the melt material, only the higher-frequency part of the spectrum is used for the evaluation, which part is caused by the reflection of the radar beams on the molten mass or the bulk material to be melted, which are further away from the radar antenna than the axial end of the beam control tube facing away from the radar antenna.

It is advantageous if the cross-section dimensions of the tube inner cavity of the beam control tube are smaller than the corresponding outer cross-section dimensions of the radar system. If the radar system is arranged outside the inner space of the melting chamber and outside the wall opening of the outer wall of the melting chamber, the cross-section of the wall opening of the outer wall therefore only has to be dimensioned for the relatively small cross-section of the beam control tube. This further reduces thermal losses at the wall opening.

In a further development of the invention, it is intended, so as to reduce the beam width of the radar lobe emitted from the radar antenna, that the radar system have a dielectric, preferably elliptical lens, and that the dielectric lens be arranged between the radar antenna and the beam control tube. The enables the coupling of a radar lobe with a very small beam width into the beam control tube, which enables a small cross-section dimension of the beam control tube. The dielectric lens is preferably designed as a solid lens body, which has a coupling area for the radar beams and a cover area. The cover area lies in the surface of an imaginary rotation ellipsoid. The coupling area is arranged between the two focal points of the rotation ellipsoid and at a distance from these, such that one focal point (F1) of the rotation ellipsoid is arranged outside the lens body and the other focal point (F2) is arranged inside the lens body. Preferably, the coupling area lies in a straight line orthogonal to the straight line running through the two focal points (F1 and F2). The radar antenna or its virtual emission point is arranged in the focal point (F1) located outside the lens body. The diameter of an elliptical lens can be six times, if necessary at least eight times, and preferably at least ten times wavelength A of the radar beams. The dielectric lens can be designed such that the beam width α of the radar lobe referenced to the virtual emission point of the radar antenna is less than or equal to 6°, in particular less than or equal to 5°, and preferably less than or equal to 4°.

It is advantageous if the dielectric lens is designed such that the beam width α of the radar lobe referenced to the virtual emission point of the radar antenna fulfills the inequation

$$α \leq 2 arctan \frac{d}{2 a}$$

where d is the clear cross-section dimension of the tube inner cavity of the beam control tube and a is the distance that the virtual emission point of the radar antenna has along the longitudinal center axis of the beam control tube to the tube inner cavity of the beam control tube. Thus, the longitudinal center axis of the radar lobe preferably matches the longitudinal center axis of the beam control tube. This enables low-loss coupling of the radar beams emitted from the radar antenna into the beam control tube.

For thermal shielding of the radar system from the temperatures prevalent at the end of the beam control tube distanced from the radar system, in a preferred embodiment of the invention a radar-transparent dielectric window is arranged in the tube inner cavity of the beam control tube. This preferably extends across the entire cross-section of the tube inner cavity of the beam control tube. When using the device to measure the level of a molten mass and/or a material to be melted in a melting furnace, in addition to the thermal radiation of the melting furnace the dielectric window also keeps gases and aerosols emanating from the melting furnace away from the radar system.

A practical embodiment of the invention stipulates that the beam control tube has at least a first tube section and a second tube section arranged as a straight extension of the first section, and that the radar-transparent window be arranged between these tube sections and connects them to one another. The radar-transparent filter is positioned at a distance from the axial end of the beam control tube that is at a distance from the radar system, in order to reduce the thermal load of the radar-transparent window when high temperatures occur at this axial end. Preferably, for this purpose this radar-transparent window is positioned on or immediately adjacent to the opposing other axial end of the beam control tube in the tube inner cavity of the beam control tube, and is preferably connected gas-tight with the inner wall of the beam control tube.

It is advantageous if the normal on the surface of the radar-transparent window is tilted under an inclination angle β relative to the longitudinal center axis of the beam control tube, which angle is greater than half of the −3 dB beam width α of the radar lobe emanating from the lens. Thus direct reflection of the radar beams emitted from the radar antenna at the radar-transparent window, which are received by the radar antenna, are reduced. This improves the measurement dynamics of the radar system. The distances of the interfering reflections occurring on the radar-transparent window cannot be changed and are less than the distance to the measurement object. Also, the signal amplitudes of these interfering reflections are less than the useful signal. As a result, these can be filtered out using suitable electronic signal processing. The inclination angle β is preferably at least 4°.

Preferably, the radar system for emitting radar beams is equipped with a wavelength λ, whereby the clear cross-section dimension of the tube inner cavity of the beam control tube is between two times and fifty times wavelength λ, if necessary between two times and thirty times wavelength λ, preferably between two times and twenty times and in particular between ten times and fifty times wavelength λ. Wavelength λ refers to the free space wavelength of the radar beams.

In a further development of the invention, it is intended that the radar electronics unit have a differentiating circuit to record a change of a distance measurement signal, and that the differentiating circuit is connected to a comparator to compare the change of distance measurement signal to a reference value or reference value range. For a melting furnace where the device according to the invention is used to measure the level of a molten mass located in a melting chamber and/or a bulk material to be melted, such as scrap or granulate for example, it can be used to determine the time at which all bulk material, which was filled into the melting chamber, has melted. This assumes that when the distance measurement signal does not change any longer or the change is less than the reference value, essentially all bulk material to be melted has melted and therefore the melting process is ended.

For melting furnaces, where below the surface of the melted mass there can remain unmelted bulk material at the time where the distance measurement signal no longer changes, if necessary a predetermined period of time can be set to elapse after it was detected that the distance measurement signal no longer changes, This time period should be measured in such a manner that ensures that after this time period elapses the melting process is ended, meaning there is no additional unmelted bulk material in the interior space of the melting furnace, including within the molten mass.

To date, the time period of complete melting of the melt material in the melting furnace could only be determined insufficiently. In the state of the art, an optical window or opening in the melting furnace is manually observed by a worker at irregular intervals, who then subjectively decides whether the melting process is ended. The disadvantage of this procedure is also that complete melting is frequently difficult to determine, and therefore the furnace process is maintained longer than necessary as a precaution. This consumes an unnecessarily high level of energy.

Using the previously mentioned further development of the invention, the end of the melting process can now be determined very precisely. Thus, the melting process can be operating energy-efficiently by optimizing temperature and time. A significant energy saving is thus possible and through the time saving the capacity of the furnace can be increased, saving costs to a significant extent. If necessary, the volume of the melt can additionally be determined very precisely through the distance measurement at the end of the melting process, if the geometry of the melting furnace melting chamber is known.

Typically, the melting process begins when the melt material begins to melt. The melt material initially is distributed inhomogenously in the furnace. Depending on the furnace design, there is inhomogenous distribution in the angle of repose of the melt material to be melted or in ridges at the edge or another location of the interior space of the melting chamber. During melting, the melt material begins to sink into the molten mass, whereby the distance to the furnace ceiling changes. When the melt material is fully melted, the distance no longer changes and the surface of the molten mass determines the distance to the furnace ceiling. The measurement device that measures this distance must cope with the conditions of high temperature, the inherent radiation of the molten mass and the melt objects, vapors and smoke, as well as the plasma or burner flames in the furnace.

In a preferred embodiment of the invention, the device has a radar housing connected to the axial end of the beam control tube facing the radar antenna, which housing delineates a receiving area in which the radar system is arranged, whereby the radar housing has an opening for the radar beams on the axial end of the beam control tube facing the radar antenna, and whereby the radar housing has at least one inlet opening to feed cooling gas into the receiving area and at least one outlet for the cooling gas. This enables effective cooling of the radar system, which makes the device particularly suitable for use in or on a melting furnace.

In an advantageous embodiment of the invention, it is provided that the beam control tube has an inlet to feed in cooling gas, in a section of the tube inner cavity located between the radar-transparent window and the axial end of the beam control tube spaced apart from the radar antenna. Additionally, through this measure the temperature of the radar system can be reduced when using the device in or on a melting furnace. The cooling gas can be air, nitrogen, or preferably an inert gas such as argon or helium. The cooling gas fed to the inlet flows through the section of the tube inner cavity located between the radar-transparent window and the axial end of the beam control tube spaced apart from the radar antenna, and then exits at the axial end of the beam control tube spaced apart from the radar system, into the interior space of the melting furnace melting chamber.

With regard to the melting furnace of the type mentioned initially, the task mentioned above is accomplished in that the melting furnace has the device according to the invention, whereby the beam control tube of the device passes through the wall opening in the outer wall of the melting furnace, and is connected tightly to the outer wall with its outer circumference, and whereby the radar system is arranged on the axial end of the beam control tube spaced apart from the interior space of the melting chamber, preferably outside the wall opening.

Through distance measurement according to the time-of-flight principle, the level of the molten mass located in the interior space of the melting furnace or of the material to be melted in the interior space can be measured with the help of the radar system. By differentiating the distance signal and comparing the differentiated signal obtained with a limit value or limit value range, additionally the time point at which a melt process running in the melting chamber is ended can be determined.

In a preferred embodiment of the melting furnace, the beam control tube has a tube section that projects into the interior, on the inner surface of the outer wall containing the wall opening, which surface faces the interior space, whereby this tube section—extending from the wall opening to the end of the tube section spaced away from the opening—preferably has a component facing downward. After the radar beam exits the beam control tube the radar beam diverges. Thus, the radar beam intensity drops at 1/R². Here, R is the shortest distance between the free end of the tube section that projects into the interior space and the molten mass or bulk material to be melted. The radar beam is reflected on the molten mass or the bulk material to be melted. The intensity of the radar beam, which again is coupled into the beam guide tube, drops once again at 1/R². The following applies for the relationship between the exiting millimeter wave power P_{T} to receive power P_{R}

$$\frac{{P}_{R}}{{P}_{T}} < {R}^{- 4}$$

For reliable radar distance measurement, therefore, the end of the beam control tube must be arranged as close as possible to the molten mass or bulk material to be melted, in order to keep R in the above inequation as small as possible. On the other hand, R must be large enough that the beam control tube is not melted by the hot melting furnace temperature. Both can be achieved in that both the length of the tube section that projects into the interior space and the cooling gas stream are dimensioned accordingly.

The wall opening, through which the beam control tube passes, is preferably arranged in the ceiling of the melting chamber. But it can also be arranged in a side wall of the melting chamber. If necessary, it is even possible that a deflecting mirror for the radar beams is arranged in the beam control tube, by means of which the radar beam emitted from the radar antenna can be outcoupled from the beam control tube in the emission direction, behind the deflecting mirror, with its longitudinal center axis transverse to the longitudinal center axis of the beam control tube.

### BRIEF DESCRIPTION OF THE DRAWINGS

Additional details, characteristics, and benefits of the present invention can be determined from the following description of an exemplary embodiment, taking into account the drawing.

It shows:

FIG. 1 a longitudinal section of a device to perform radar measurements on a molten mass contained in the interior space of a melting chamber, whereby the center axis of a beam control tube of the device is in the section plane of the drawing,

FIG. 2 a partial longitudinal section of the device, which shows a radar system arranged in a radar housing, whose radar beams are coupled into the beam control tube, where the radar beams emitted from the radar system in lobe shape are indicated by a dot-dash line,

FIG. 3 a longitudinal section of a melting furnace, which has the device shown in FIGS. 1 and 2, where the melting furnace is shown in very simplified manner, and

FIG. 4 a partial longitudinal section through the axial end of the beam control tube spaced away from the radar system, where wave fronts of the radar beams are shown as dashed lines.

### DESCRIPTION OF THE INVENTION

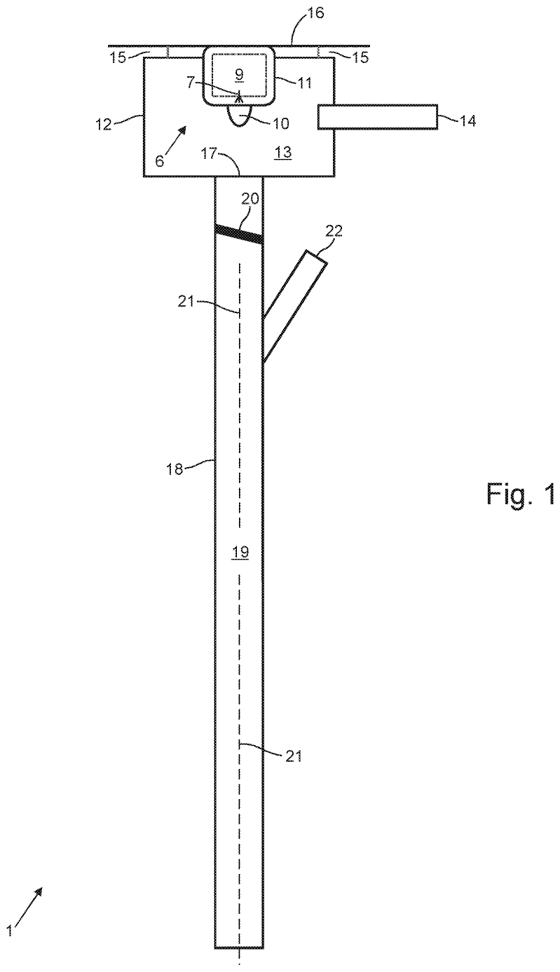

The device identified as a whole as 1 in FIG. 1, to perform distance measurements on a melted mass 4 located in the interior space 2 of a melting chamber 3 and/or a bulk material 5 to be melted, located in the interior space, is equipped with a radar system 6, which has a radar antenna 7, only shown schematically, to emit and receive radar beams 8, and an interacting radar electronics unit 9, in the manner known for distance measurement according to the time-of-flight principle. The radar wave length of the radar beams emitted from the radar antenna 7 is approx. 2.5 mm. The radar antenna 7 is a combined radar antenna that transmits and receives radar beams. To separate the transmit and receive signals, the radar system 6 has a directional coupler not further shown in the drawing. Other designs are also possible, however, where the radar system has two adjacent radar antennas, one serving as a transmission antenna and the other as a receiver antenna.

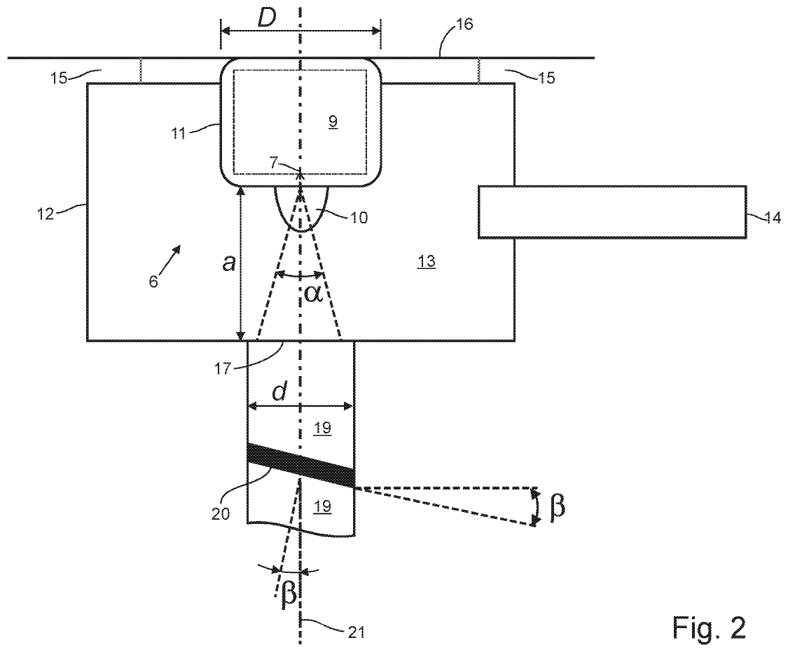

To reduce the beam width α of the radar lobe emitted from the radar antenna 7, the radar system 6 has a dielectric elliptical lens 10 made of Teflon, which reduces the −3 dB beam width α of the radar lobe to less than 4°. In FIG. 2, the beam width α is shown larger for legibility purposes. The beam width is based on the virtual emission point of the radar antenna.

The distance a between the virtual emission point of the radar system 6 and the beam control tube 18 is selected such that the radar beams 8 couple into the tube inner cavity 19 with an inside diameter d. For this, the inequation

$$tan \frac{α}{2} \leq \frac{d}{2 a}$$

must be fulfilled.

As shown schematically in FIG. 2, the radar electronics unit 9 is arranged in an electronics housing 11. The radar system 6, including the electronics housing 11 and the lens 10, is located in an air-cooled radar housing 12, which delineates a receiving area 13 for the radar system 6. The radar housing 12 has an inlet opening 14 to feed cooling gas into the receiving area 13.

The radar housing 12 has a lower housing section that is connected, at its top side, to a cover 16, on which the radar system 6 is installed. Between the cover 16 and the lower section of the radar housing 12, a slit-shaped outlet 15 connected to the receiving area 13 is provided, from which outlet the cooling air can exit from the receiving area 13. On its underside opposite the cover 16, the radar housing 12 has an opening 17 for the radar beams to pass through. Through this opening, the radar lobe emitted from the lens 10 can exit the radar housing 12. The radar housing 12 is round and has a diameter of 125 mm, a wall thickness of 2 mm, and a height of 135 mm. The radar housing 12 does not necessarily have to be round and can have another shape.

As can be seen in FIGS. 1 and 2, the device has a beam control tube 18 with an inner wall delineating a tube inner cavity 19. The beam control tube 18 is of a circular cylindrical design with an inside diameter of 50 mm and is made of stainless steel. Other designs are also possible, however, where the beam control tube 18 has a polygonal cross-section, for example, and/or is made of another heat-resistant material.

The beam control tube 18 is open for the radar beams at both axial ends, and is arranged with its longitudinal center axis 21 in a straight extension of the main emission direction of the radar lobe emitted from the lens 10. At one axial end, the beam control tube 18 is connected to the border area of the radar housing 12 defining the opening 17. The radar antenna 7 and the lens 10 are oriented such that the radar beams 8 emitted from the radar antenna are coupled into the tube inner cavity 19 at this axial end, and then pass through the tube inner cavity 19 to the opposing other axial end of the beam control tube 18, and from there exit from the beam control tube 18.

The diameter of the lens 10 is 32 mm. The distance between the virtual emission point of the radar system and the beam control tube 18 is 60 mm, and is therefore larger than the diameter of the lens 10. The small −3 dB beam width of the radar lobe emitted from the lens 10, of less than 4°, the distance from the lens 10 to the beam control tube 18 of 60 mm, and the inside diameter of the beam control tube 18 of 50 mm ensures that the predominant share of the radar waves emitted from the radar system 6 couple into the tube inner cavity 19. The inner wall defining the tube inner cavity 19 is designed to be reflective for the radar beams 8. Thus, the radar beams 8 can pass through the beam control tube 18 at low loss.

If the radar beams 8, after exiting from the beam control tube 18, meet an object on which they are reflected, the reflected wave impacts the outlet point of the beam control tube 18 once again, passes through the beam control tube 18, and is then received by the radar system 6.

Because of the diameter d of the tube inner cavity 19, which is 20 times larger than the radar wave length of 2.5 mm, the beam control tube 18 acts like a multimodal waveguide. The multimodal waveguide results in modal dispersion, which lowers the measurement precision of the radar system 6. For the application in the melting furnace, a measurement precision of better than 5 mm is fully sufficient, however, so that modal dispersion is no longer disturbing here.

As can be seen in FIG. 2, the clear cross-section dimension d of the tube inner cavity 19 of the beam control tube 18 is smaller than the corresponding outer cross-section dimension D of the radar system 6. The radar system therefore extends laterally beyond the cover surface of the straight extension of the tube inner cavity 19 projected in the axial direction of the beam control tube 18.

For thermal shielding of the radar antenna 7 against the temperatures prevalent at the end of the beam control tube 18 spaced away from the radar system 6, a dielectric window 20, which is transparent for the radar beams, is arranged in the tube inner cavity 19 of the beam control tube 18.

Due to the dielectric constant of the window 20, which is greater than 1 mm, there is a partial reflection of the radar beams on the window surface. To prevent the partial reflection from coupling directly into the receiver of the radar system 6, the surface of the dielectric window 20 is tilted by an angle β to the longitudinal center axis 21 of the beam control tube 18, which angle fulfills the following inequation:

$$β > \frac{α}{2}$$

The radar-transparent window 20 is designed to be disk-shaped and the angle β in the exemplary embodiment is at least 4° (FIG. 2).

The radar-transparent window 20 is located between a first tube section of the beam control tube 18 and a second tube section of the beam control tube 18 arranged as a straight extension of the first section. The first tube section extends from the axial end of the beam control tube 18 that faces the radar system 6 to the window 20, and the second tube section extends from the window 20 to the other axial end of the beam control tube 18. The second tube section is longer than the first tube section. The tube sections can be connected to one another as one piece or in another manner. The dielectric window 20 can, for example, be made of Teflon, nylon, ceramic, or another suitable dielectric material, and must be at least partially transparent for the radar beams 8.

The beam control tube 18 has an inlet 22 to feed cooling gas, between the radar-transparent window 23 and the section of the tube inner cavity 19 located at the axial end of the beam control tube 18 that is spaced away from the radar antenna 7.

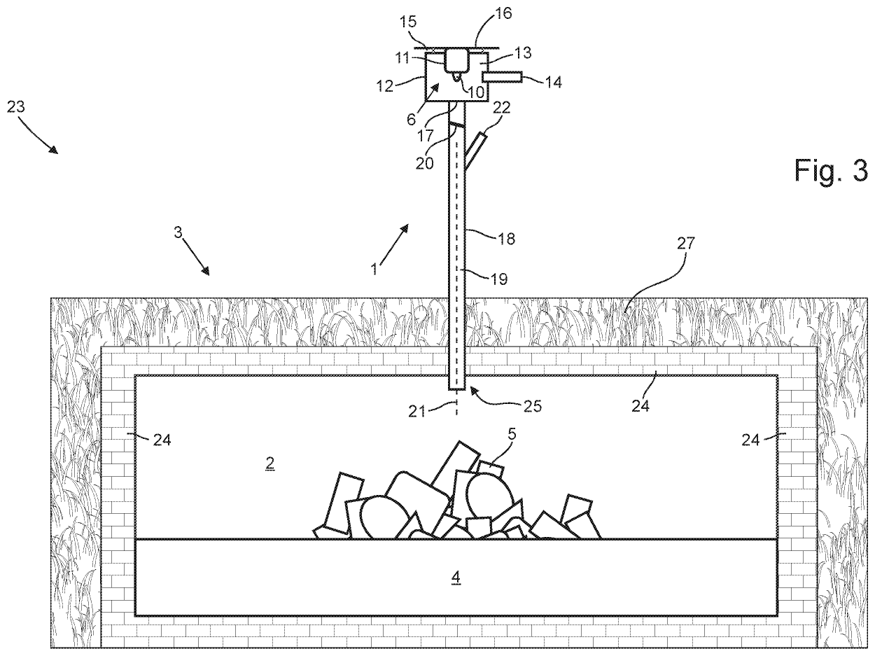

FIG. 3 shows a longitudinal section through a melting furnace 23 along the vertical plane. The melting furnace 23 has, in its interior, the melting chamber 3 already mentioned, which can be heated by means of a heater not further shown in the drawing. The melting chamber 3 has an interior space 2 with a receiving area for molten mass 4. On the floor of the melting chamber 3 there is, in addition, bulk material 5 to be melted, which extends beyond the level or the surface level of the molten mass 4.

The interior space 2 of the melting chamber 3 is delineated by outer walls 24. On the outer side, facing away from the interior space 2, these walls have a thermal insulation layer 27 not further shown in the drawing, which consists of mineral wool or a similar insulant.

Above the receiving area for the molten mass 4, the ceiling of the melting chamber 3 has a wall opening 25 through which the beam control tube 18 of the device 1 passes. On its outer circumference, the beam control tube 18 is connected to the ceiling of the melting chamber 3, forming a seal.

The radar system 6 is arranged above the wall opening 26, at a distance from the ceiling. The lower end of the beam control tube 18 spaced away from the radar system 6, projects out of the wall opening 26 at the underside of the ceiling and protrudes into the interior space 2 of the melting chamber 3 such that it is distanced from the molten mass 4 and the bulk material 5.

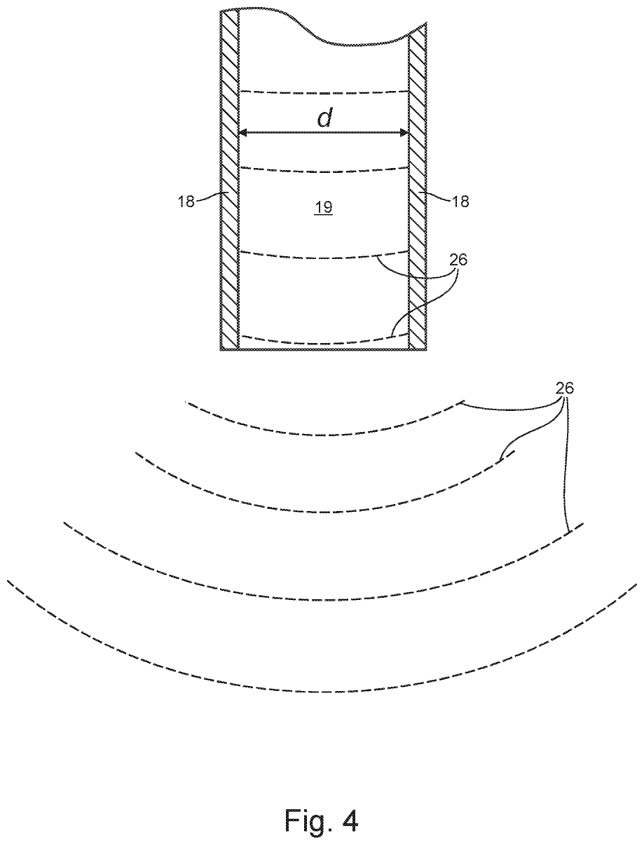

FIG. 4 shows the stylized phase fronts 26 when the radar waves exit the beam control tube 18. The representation is extremely simplified because only approximately flat wave fronts propagate in the tube inner cavity 19. At the end of the beam control tube 18, the radar beam diverges. Thus, the radar beam intensity drops at approx. 1/R². Here, R is the shortest distance between the plane that stretches from the outlet opening of the beam control tube 18, and the bulk material 5 or surface of the molten mass 4.

After reflection of the radar beam on the bulk material 5 or molten mass 4, it again couples into the beam control tube 18. For this reason, the radar beam intensity drops 1/R² again. The following applies for the relationship between the transmitted millimeter wave power P_{T} to receive power P_{R}

$$\frac{{P}_{R}}{{P}_{T}} < {R}^{- 4}$$

The end of the beam control tube 18 spaced away from the radar system 6 should therefore be as close as possible to the bulk material 5 or molten mass 4, to keep R as small as possible. However, R must be large enough so that the beam control tube 18 is not damaged by the hot melting furnace temperature.

From the time of flight of the radar wave, the distance to the molten mass 4 or bulk material 5 can be determined according to a known radar procedure. To keep the high temperature within the melting furnace 23 away from the radar system 6, the inlet 22 of the beam control tool 18 is connected to a gas feed not further shown in the drawing, which blows cool gas, for example air, helium, argon, or nitrogen, into the inlet 22.

This causes cooling of the beam control tube 18, the dielectric window 20, and ultimately also the radar housing 12, with the radar system contained therein.

To record a change in the measured distance to the bulk material 4 to be melted or the molten mass 5, the radar electronics unit 9 has a differentiating circuit not further shown in the drawing. To compare the change of the distance measurement signal with a reference value or reference value range, the differentiating circuit is connected to a comparator that initiates a display device. The differentiating circuit and the comparator can be realized in the form of hardware or suitable software running on a microcomputer.

At the beginning of the melting process, the bulk material 5 forms a heap, for example, and the radar system 6 measures a short distance to the bulk material 5. In the further course of melting, a liquid molten mass 4 forms. The level of the liquid molten mass 4 increases over time. The bulk material 5 not yet melted sinks into the molten mass 4 over time. Thus the distance measured by the radar system 6 increases. When the radar system 6 no longer registers a temporal change of distance, the material to be melted is fully melted and the radar system 6 measures the distance to the level of the molten mass 4. From the known geometry of the melting chamber 3, the volume of the molten mass 4 is then determined.

It is also possible to measure the distance to the floor of the melting chamber 3 before starting the melting process, using the radar system 6. When the bulk material 5 begins to melt, the floor is covered by the molten mass 4 so that the radar system measures the distance to the molten mass 4. In this way, the measured distance decreases. When the entire bulk material 5 is melted or submerged in the molten mass 4, the measured distance no longer changes and the display device for ending the melting process is activated.

If needed, a delay circuit can be arranged between the differentiating circuit of the radar electronics unit 9 and the display device. When the comparison between the distance measurement signal and the reference value or reference value range indicates that the distance measurement signal is no longer changing or only changing insignificantly, in this case the display device does not activate until the time delay elapses, in order to be certain.

1. A device to perform distance measurements on a melted mass located in the interior space of a melting chamber and/or a bulk material to be melted located in the interior space, having a radar system, which has at least one radar antenna to emit and receive radar beams, and an interacting radar electronics unit, which is designed for distance measurement according to the time-of-flight principle, wherein the device has a beam control tube with an inner wall that reflects the radar beams and surrounds a tube inner cavity, that the beam control tube is open at both axial ends for the radar beams and the radar antenna faces one of the axial ends of the beam control tube, and that the radar system is designed and oriented so that the radar beams it emits go through the tube inner cavity of the beam control tube to the opposing other axial end of the beam control tube, and exit the beam control tube there.

2. The device according to claim 1, wherein the cross-section dimensions (d) of the tube inner cavity are smaller than the corresponding outside cross-section dimensions (D) of the radar system.

3. The device according to claim 1, wherein the radar system, so as to reduce the beam width (α) of the radar lobe emitted from the radar antenna, has a dielectric, preferably elliptical lens, and that the dielectric lens is arranged between the radar antenna and the beam control tube.

4. The device according to claim 3, wherein the dielectric lens is designed such that the −3 dB beam width α of the radar lobe referenced to the virtual emission point of the radar antenna fulfills the inequation
$$α \leq 2 arctan \frac{d}{2 a}$$
where d is the cross-section dimension of the tube inner cavity of the beam control tube and a is the distance that the virtual emission point of the radar antenna has along the longitudinal center axis of the beam control tube to the tube inner cavity of the beam control tube.

5. The device according to claim 3, wherein the dielectric lens is designed such that the beam width α of the radar lobe referenced to the virtual emission point of the radar antenna is less than or equal to 6°, in particular less than or equal to 5°, and preferably less than or equal to 4°.

6. The device according to claim 1, wherein for thermal shielding of the radar system from the temperatures prevalent at the end of the beam control tube distanced from the radar system, a radar-transparent dielectric window is arranged in the tube inner cavity of the beam control tube.

7. The device according to claim 6, wherein the beam control tube has at least a first tube section and a second tube section arranged as a straight extension of the first section, and that the radar-transparent window is arranged between the tube sections and connects them to one another.

8. The device according to claim 6, wherein the radar-transparent window is designed in a disk shape, and that the normal of the plane extended on the surface of the radar-transparent window is tilted at an inclination p relative to the longitudinal center axis of the beam control tube, which inclination is greater than half of the −3 dB beam width α of the radar lobe emanating from the lens.

9. The device according to claim 1, wherein the radar system for emitting radar beams is configured with a wavelength λ, and that the clear cross-section dimension of the tube inner cavity of the beam control tub is between two times and fifty times wavelength λ, if necessary between two times and thirty times wavelength λ, preferably between two times and twenty times and in particular between ten times and fifty times wavelength λ.

10. The device according to claim 1, wherein the radar electronics unit has a differentiating circuit to record a change of a distance measurement signal, and that the differentiating circuit is connected to a comparator to compare the change of the distance measurement signal to a reference value or reference value range.

11. The device according to claim 1, wherein the device has a radar housing connected to the axial end of the beam control tube that faces the radar antenna, which housing delineates a receiving area in which the radar system is arranged, that the radar housing has a passage for the radar beams at the axial end of the beam control tube that faces the radar antenna, and that the radar housing has at least one inlet opening to feed cooling gas into the receiving area and at least one outlet for the cooling gas.

12. The device according to claim 6, wherein the beam control tube has an inlet to supply cooling gas in a section of the tube inner cavity located between the radar-transparent window and the axial end of the beam control tube spaced from the radar antenna.

13. The melting furnace, with a melting chamber delineated by exterior walls, which chamber delineates an interior space with a receiving area for a molten mass, whereby at least one exterior wall has a wall opening, which is arranged higher than the receiving area for the molten mass, and with a device according to claim 1, whereby the beam control tube of the device passes through the wall opening, and is connected with the outer wall with its outer circumference in a sealed manner, and whereby the radar system is arranged at the axial end of the beam control tube, spaced away from the interior space of the melting chamber, preferably outside the wall opening.

14. The melting furnace according to claim 13, wherein the beam control tube has a tube section projecting into the interior space on the inner surface of the outer wall containing the wall opening, which surface faces the interior space, and that this tube section—extending from the wall opening to the end of the tube section spaced away from the wall opening—preferably has a component facing downward.

15. The melting furnace according to claim 13, wherein the melting chamber has a floor, side walls, and a ceiling, and that the wall opening through which the beam control tube passes is arranged in the ceiling of the melting chamber.
